(19) United States
(12) Patent Application Publication
(10) Pub. No.: US 2003/0098806 A1
(43) Pub. Date: May 29, 2003

(54) Rejecting interference for simultaneous received signals

(76) Inventor: Evan R. Green, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/996,176

(22) Filed: Nov. 27, 2001

(51) Int. Cl. H03M 1/12; H04L 1/00; H03D 1/06

(52) U.S. Cl. 341/144; 341/155; 455/296; 375/346

(57) ABSTRACT

A wireless data system for reducing interference where simultaneous transmission and reception may occur in the same frequency band. A transmitter may include a Digital-to-Analog Converter (DAC), an up converter to prepare a digital value for transmission. A receiver may include a subtractor circuit, a down converter, an Analog-to-Digital Converter (ADC) to prepare a received analog signal for storage as a digital value. The wireless data system includes an adaptive interface cancellation circuit to generate a delayed replica signal of the original transmitted signal. The subtractor circuit may inject an out-of-phase signal into the receiver front end to cancel the interference in the received signal.

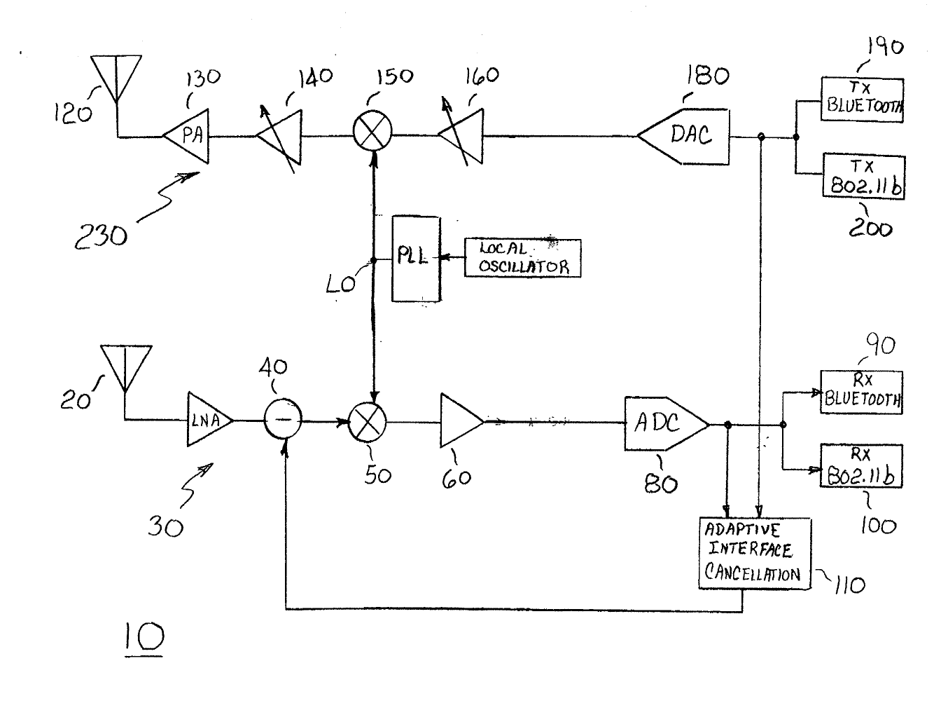

### BACKGROUND

Today's portable communication products need Radio Frequency (RF) integrated circuits that perform well. These products may operate in close proximity to one another, making these circuits highly susceptible to disturbance through many different coupling mechanisms. To establish a two-way communication link between these electronic products, the transmit signal should be differentiated from the desired signal to be received. Further, new generations of wireless electronic devices may transmit on the same frequency that the receiver needs. Under these conditions the operating frequencies may not be separated far enough apart to prevent interference. A time sharing approach, where only one radio transmitter operates at a time, may solve the problem of collisions. However, this approach may preclude certain desired modes of operation.

To operate these communication products simultaneously, the receiver should to be presented with an undistorted signal that may be higher in power than the interfering signal. Thus, there is a continuing need for better ways to differentiate the desired signal to be received and solve the mutual interference problem in order that the radio transceivers may correctly decode data when operating in close proximity.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

The sole FIGURE is a block representation of a portion of an integrated circuit having a transceiver in accordance with an embodiment of the present invention.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

The terms “coupled” and “connected,” along with their derivatives, may be used in the description and claims. These terms are not intended as synonyms for each other. Rather, “connected” may be used to indicate that two or more elements are in direct physical or electrical contact with each other. “Coupled”may mean that two or more elements are in direct physical or electrical contact. However, “coupled” may also mean that two or more elements are not in direct contact with each other, but yet still co-operate or interact with each other.

Unless specifically stated otherwise, as apparent from the following discussions, it is appreciated that throughout the specification terms such as “modulation,” “demodulation,” or the like, refer to the action and/or processes of a transceiver or radio system, or similar electronic device, that manipulate and/or transform signals. Embodiments of the present invention include functional blocks arranged in the radio system to perform the operations herein. This radio system may be specially constructed for the desired purposes or integrated and embedded to operate with other functional blocks.

It should be understood that embodiments of the present invention may be used in a variety of applications. Although the present invention is not limited in this respect, the circuits disclosed herein may be used in many communication products such as cell phones, two-way radio communication systems, one-way pagers, two-way pagers, personal communication systems (PCS), or the like. The architecture presented in the embodiments of the invention may have applications to additional products in portable laptop computing, networking, digital camera applications, and a wide range of consumer products based on wireless technology for instrumentation and automotive.

Turning to the sole FIGURE, a transceiver 10 in accordance with the present invention is described. As a portion of a radio system, transceiver 10 may be integrated and include, for example, a microprocessor, a Digital Signal Processor (DSP), a microcontroller, a Reduced Instruction Set Computing (RISC) processor, or an embedded core. It should be understood that only the transceiver portion of the integrated circuit is included in the FIGURE. The integrated circuit may also optionally include other components such as a memory that may be used to store instructions to be executed by the integrated circuit.

The modulated Radio Frequency (RF) signals received at an antenna 20 contain information that may be recovered in a receiver 30 of the electronic system. A Low Noise Amplifier (LNA) 30 may receive and amplify the incoming modulated RF signals. A subtractor circuit 40 may be connected to the output of LNA 30. The output signal from subtractor circuit 40 may be passed to RF mixer 50 along with a generated Local Oscillator (LO) signal. RF mixer 50 may down convert the high frequency modulated signal to a lower Intermediate Frequency (IF) signal. Thus, the modulated signal and the LO signal may be “mixed” to translate the carrier frequency of the modulated signal from the RF range to the IF range. The down converted signals may then be amplified by a gain amplifier 60. The amplified signal may be converted by an Analog-to-Digital Converter (ADC) 80 from analog signals to a digital value that is proportional to the input value of the analog signals. The digital values following the Bluetooth Special Interest Group (Bluetooth SIG) specification may be processed in the remaining portion of a Bluetooth receiver 90 and the digital signals following the Institute of Electrical and Electronics Engineers (IEEE) 802.11b specification may be processed in the remaining portion of an 802.11b receiver 100. Receiver 90 may include channel filters, a demodulator and circuits for other baseband processing for Bluetooth and receiver 100 may include channel filters, a demodulator and circuits for other baseband processing for IEEE 802.11b.

A transmitter 230 of transceiver 10 may transmit data formatted in accordance with the Bluetooth specification as received from TX Bluetooth block 190 or data formatted for the IEEE 802.11b specification as received from TX 802.11b block 200. TX Bluetooth block 190 may provide the baseband processing for Bluetooth such as, for example, symbol mapping and modulation, among other processing functions. TX 802.11b block 200 may provide the 802.11 baseband processing. Transmitter 230 may use a Digital-to-Analog Converter (DAC) 180 to generate analog output signals that are proportional to the input value of the digital values stored in the register. The analog signal may be provided to a gain amplifier 160. The output signal from gain amplifier 160 may be passed to mixer 150 along with a generated Local Oscillator (LO) signal. Mixer 150 may up convert the modulated signal to an RF signal. The up converted signals may then be amplified by a gain amplifier 140 and passed to antenna 120 for transmission.

Transceiver 10 includes an adaptive interface cancellation circuit 110. Cancellation circuit 110 may receive data from receiver 30 and transmitter 230 and generate an output signal that may be fed back to subtractor circuit 40. More specifically, cancellation circuit 110 may receive the data presented to DAC 180 and the data generated by ADC 80. The data at the input to DAC 180 may be a high quality copy of the signal that is being prepared for transmission. The data at the output of ADC 80 may be another copy of that transmitted signal as received through receiver 30.

In operation, an electronic device such as transceiver 10 may operate different protocols and may receive signals whose frequencies periodically overlap. In such cases, transmitter 230 may transmit on the same frequency that receiver 30 or another transceiver is transmitting and a collision may occur. In other words, the electronic device may process signals that overlap when both devices are transferring information. Although the scope of the present invention is not limited in this respect, one transceiver may be selected to process signals using the Institute of Electrical and Electronics Engineers (IEEE) 802.11b specification while another transceiver may process signals using the Bluetooth specification. Thus, the integrated RF front end of the transceiver may simultaneously carry both Bluetooth and IEEE 802.11b signals. It should be pointed out that two devices, one operating with IEEE 802.11b and another with Bluetooth radio, may operate in common frequency space about 28 percent of the time (79 hopping channels at 1 MHz each divided by 22 MHz=28%). Thus, without adaptive interface, the opposing transmitters may have interference about 28 percent of the time.

By using adaptive cancellation techniques, cancellation circuit 110 and subtractor 40 cooperate to reduce signal interference. A copy of the signal that is being transmitted by transmitter 230 may be subtracted from the signal that contains interference being received by receiver 30, allowing receiver 30 to generate an undistorted signal that may be higher in power than the interfering signal. Thus, a communications circuit having a receiver and a transmitter may process a receiver signal with a transmitter signal in cancellation circuit 110 and generate an out-of-phase signal that may be used in the receiver to reduce interference.

Cancellation circuit 110 may process algorithms to remove the interference.

Thus, the cancellation techniques employed by an embodiment of the present invention may be used to mitigate the interference problem. It should be pointed out that the interfering signal may be a result of direct coupling between transmit antenna 120 and receive antenna 20 or may be a result of indirect coupling as the transmitted RF signal reflects off nearby objects. For either case, cancellation circuit 110 may process the interfering signals as propagation rays or delay lines. The adaptive canceling process may estimate the delay by correlating the received signal with the transmitted signal. A delayed replica signal of the original transmitted signal may be generated and injected out-of-phase into the receiver front end to cancel the interference in the received signal. The correct amplitude for the canceling signal may be found by either measuring the interference power for the ray or by iterating to reduce the interference.

It is intended that architectural selections within transceiver 10 not limit the present invention. Examples of the architectural selections include, but are not limited by, the specific method of data conversion employed by the DAC and ADC and the use and placement of filters in the signal paths of tranceiver 10. More specifically, DAC 180 may or may not be a folded DAC. Further, the resolution of DAC 180 and ADC 80 as related to the number of bits, the voltage range, linearity, among other performance criteria, are not intended to be limiting. It is further assumed that the accuracy of matching components within ADC 80 and DAC 180, and hence the general accuracy, is adequate for use in transceiver 10.

Although filters have not been shown in the FIGURE, it should be understood that transceiver 10 may include filters and the filters may be placed dependent upon the architecture employed. By way of example, transmitter 230 may include a filter inserted in the signal path between gain amplifier 160 and mixer 150 and an additional filter inserted between gain amplifier 140 and power amplifier 130. Neither the number of filters nor the placement of filters within transceiver 10 is intended to be limiting. It should be further understood that the circuits disclosed herein may use differential signals, quadrature signals or single-ended signals without limiting the scope of the invention.

Transmitter 230 may perform modulation, up-conversion and power amplification. Modulation and up-conversion may be performed in two steps in an architecture denoted either as dual conversion or two-step conversion (as shown in the FIGURE). Alternatively, modulation and up-conversion may be performed in one step in an architecture denoted as direct conversion. It is intended that either architecture, i.e., the one-step or two-step, be covered by embodiments of this invention.

Another architecture choice is the design of one antenna or two antenna in transceiver 10. The FIGURE depicts a two antenna architecture choice with one antenna placed in the receiver portion and another antenna placed in the transmitter portion. The two antenna may be placed orthogonal to one another to improve interference cancellation and meet a Carrier to Interferer (C/I) diversity testing design criteria. The two properly located antenna may improve the usable range of a transceiver system and allow communication through antenna diversity. However, the use of one switched antenna or multiple antenna is an architecture choice that does not limit the present invention.

By now it should be appreciated that a transceiver has been presented that uses an adaptive interface cancellation circuit to generate a delayed replica signal of the original transmitted signal. A subtractor circuit may inject an out-of-phase signal into the receiver front end to cancel the interference in the received signal. While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A communications circuit comprising a transceiver having a receiver and a transmitter, wherein a transmitter signal is processed with a receiver signal to generate an out-of-phase signal used in the receiver to reduce interference.

2. The communications circuit of claim 1 further comprising a Digital-to-Analog Converter (DAC) in the transmitter coupled to receive the transmitter signal.

3. The communications circuit of claim 2 further comprising an Analog-to-Digital Converter (ADC) in the receiver to generate the receiver signal.

4. The communications circuit of claim 3 further comprising:
a first antenna coupled to an output of the DAC to provide signals for Bluetooth and IEEE 802.11b; and
a second antenna coupled to an input of the ADC to receive Bluetooth and IEEE 802.11b signals.

5. The communications circuit of claim 4 wherein the first antenna is placed orthogonal to the second antenna.

6. A device comprising:
an Analog-to-Digital Converter (ADC) to convert data received in a receiver path;
a Digital-to-Analog Converter (DAC) to convert data to be transmitted in a transmitter path;
a cancellation circuit having a first input coupled to an input of the DAC and a second input coupled to an output of the ADC, wherein the cancellation circuit injects an out-of-phase signal into the receiver path to cancel at least a portion of interference from the transmitter path.

7. The device of claim 6 further comprising a subtractor circuit having a first input coupled to an input of the receiver path and a second input coupled to an output of the cancellation circuit.

8. The device of claim 7 further comprising a first antenna coupled to an output of the DAC to provide signals for Bluetooth and IEEE 802.11b.

9. The device of claim 8 further comprising a second antenna coupled to an input of the ADC to receive Bluetooth and IEEE 802.11b signals.

10. The device of claim 9 wherein the first antenna is placed orthogonal to the second antenna.

11. The device of claim 10 wherein the subtractor circuit has the first input coupled to the second antenna.

12. A system comprising:
a transmit path to receive transmitter digital data to convert to a transmitter analog signal;
a receive path to receive a receiver analog signal to convert to receiver digital data; and
a cancellation circuit having inputs to receive the transmitter digital data and the receiver digital data and generate an out-of-phase signal to inject into the receiver path to cancel at least a portion of interference from the transmitter path.

13. The system of claim 12 further comprising a subtractor circuit having a first input coupled to an output of the cancellation circuit and a second input coupled to receive the receiver analog signal, and an output to provide the out-of-phase signal to inject into the receiver path.

14. The system of claim 12 wherein the transmit path further includes a Digital-to-Analog Converter (DAC) having an input coupled to receive the transmitter digital data and having an output to provide the transmitter analog signal.

15. The system of claim 12 wherein the receive path further includes an Analog-to-Digital Converter (ADC) having an input coupled to receive the receiver analog signal and having an output to provide the receiver digital data.

15. The system of claim 12 wherein the receive path further includes:
a first antenna coupled to an output of the DAC to provide Bluetooth and IEEE 802.11b signals; and
a second antenna coupled to an input of the ADC to receive signals for Bluetooth and IEEE 802.11b.

16. The system of claim 15 wherein the first antenna is placed orthogonal to the second antenna.

17. A method comprising:
converting a first digital value to an analog signal in a transmitter;
converting a signal received by a receiver that contains a portion of the analog signal as interference to a second digital value; and
processing the first and second digital values to generate a signal that mitigates the interference in the signal converted by the receiver.

18. The method of claim 17, wherein processing the first and second digital values further comprises generating a signal that is out-of-phase to the portion of the analog signal contained in the signal received by the receiver.

19. The method of claim 18 further comprising subtracting the signal that is out-of-phase from the signal received by the receiver.

20. The method of claim 19 further comprising receiving the signal in the receiver orthogonal to the analog signal in the transmitter.
